(19) United States
(12) Patent Application Publication
(10) Pub. No.: US 2024/0186259 A1
(43) Pub. Date: Jun. 6, 2024

(54) PACKAGE, SEMICONDUCTOR DEVICE, AND APPARATUS

(71) Applicant: CANON KABUSHIKI KAISHA, Tokyo (JP)

(72) Inventors: IKUTO KIMURA, Kanagawa (JP); KAZUYA NOTSU, Kanagawa (JP); YOSHIHIRO MINAMI, Kanagawa (JP)

(21) Appl. No.: 18/525,500

(22) Filed: Nov. 30, 2023

(30) Foreign Application Priority Data
Dec. 2, 2022 (JP) 2022-193608

(51) Int. Cl. H01L 23/544; H01L 23/498

(52) U.S. Cl. CPC H01L 23/544; H01L 23/49811; H01L 23/49838; H01L 2223/54413

(57) ABSTRACT

A package includes a plurality of terminals, a mark portion, and a base plate. a mark for identification is provided on the mark portion. The plurality of terminals and the mark portion are provided on one surface of the base plate. A smooth portion, which is smoother than another portion between the plurality of terminals and the mark portion, is provided on the one surface and between at least one terminal among the plurality of terminals and the mark portion.

### BACKGROUND

### Field

The present disclosure relates to a package, a semiconductor device, and an apparatus.

### Description of the Related Art

A mark for product identification may be provided on a package on which a semiconductor chip is to be mounted. Japanese Patent Laid-Open No. 2013-247256 describes a two-dimensional bar code for registering an identification number of an individual circuit board being provided on a substrate on which a chip is to be arranged.

A distance between terminals and the mark for product identification decreases with an increase in the number of terminals disposed on the package, miniaturization of the package, and the like. If flux oozes from a terminal onto the mark during solder mounting, the mark for identification may become less visible.

### SUMMARY

Some embodiments of the present disclosure provide a technique for suppressing a decrease in visibility of a mark for identification.

According to an aspect of the present disclosure, a package includes a plurality of terminals, a mark portion on which a mark for identification is provided, and a base plate, wherein the plurality of terminals and the mark portion are provided on one surface of the base plate, and wherein a smooth portion, which is smoother than another portion between the plurality of terminals and the mark portion, is provided on the one surface and between at least one terminal among the plurality of terminals and the mark portion.

Further features of the present disclosure will become apparent from the following description of exemplary embodiments (with reference to the attached drawings).

### BRIEF DESCRIPTION OF THE DRAWINGS

FIG. 1 is a plan view and a cross-sectional view illustrating an example of a configuration of a package of the present embodiment.

FIG. 2 is a plan view and a cross-sectional view illustrating an example of a configuration of a semiconductor device in which the package of FIG. 1 is used.

FIGS. 3A and 3B are plan views illustrating variations of the package of FIG. 1.

FIG. 4 is a plan view and a cross-sectional view illustrating a variation of the package of FIG. 1.

FIG. 5 is a plan view and a cross-sectional view illustrating a variation of the package of FIG. 1.

FIG. 6 is a diagram illustrating an example of a configuration of an apparatus in which the package of the present embodiment is embedded.

### DESCRIPTION OF THE EMBODIMENTS

Hereinafter, embodiments will be described in detail with reference to the attached drawings. Note, the following embodiments are not intended to limit the scope of the disclosure. Multiple features are described in the embodiments, but limitation is not made that requires all such features, and multiple such features may be combined as appropriate. Furthermore, in the attached drawings, the same reference numerals are given to the same or similar configurations, and redundant description thereof is omitted.

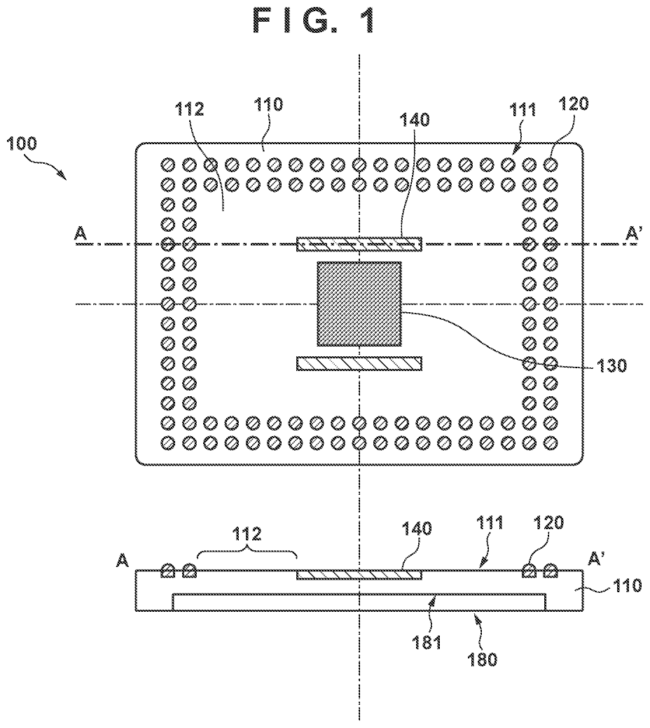

A package on which a semiconductor chip is to be mounted according to an embodiment of the present disclosure will be described with reference to FIGS. 1 to 5. FIG. 1 is a plan view and a cross-sectional view illustrating an example of a configuration of a package 100 of the present embodiment. The cross-sectional view illustrated on a lower side of FIG. 1 illustrates an A-A′ cross-section of the plan view illustrated in an upper side of FIG. 1.

The package 100 includes a plurality of terminals 120 and a mark portion 130, in which a mark for identification is provided, on one surface 111 of a base plate 110. A smooth portion 140, which is smoother than another portion 112 between the plurality of terminals 120 and the mark portion 130, is provided between at least one terminal among the plurality of terminals 120 and the mark portion 130 on the surface 111 of the base plate 110.

The base plate 110 may be constituted by an insulating base plate in which an insulator is used. Further, a wiring layer in which a conductor, such as metal, is used on the insulating base plate may be disposed on the base plate 110. The package 100 includes the terminals 120 for making electrical connections between a semiconductor chip mounted on the package 100 and devices external to the package 100 and may be utilized as a semiconductor device that is configured to include the package 100 and the semiconductor chip mounted on the package 100. In that case, the base plate 110 of the package 100 may be an insulating base plate in which ceramic that has excellent heat dissipation and electrical characteristics, such as alumina or steatite, is used.

The terminals 120 disposed on the surface 111 of the base plate 110 are connected to inner leads disposed on a mounting surface 181 on which the semiconductor chip of the base plate 110 is to be mounted via an interior wiring pattern disposed in the base plate 110. A plating layer, such as gold plating, may be formed on surfaces of the terminals 120 and the inner leads in order to achieve wettability for soldering. In a case of the terminals 120 and the inner leads in which copper-based materials are used, for example, nickel plating is applied over copper and then gold plating is applied over the nickel plating.

The mark portion 130, on which a mark used for product identification and for identification of the respective package 100 is disposed, is disposed on the same surface 111 as the terminals 120 of the base plate 110. The mark portion 130 may be disposed in a central region of the surface 111 of the base plate 110 as illustrated in FIG. 1. Here, the central region of the surface 111 of the base plate 110 may be a region internal to a set of virtual points that bisect the virtual lines connecting a central point (e.g., a position at the geometric center of gravity) of the surface 111 and each side in a projection orthogonal to the surface 111. However, arrangement of the mark portion 130 is not limited thereto and may be disposed in a suitable position according to arrangement of the terminals 120 and the like. The mark portion 130 may be a region surrounding outer edges of the mark for identification, in which characters, shapes, and the like are used and which is formed on the mark portion 130. For example, the mark portion 130 may be a region surrounded by lines connecting the outermost edges of the mark for identification, such as characters and shapes.

A data matrix, for example, may be used as a mark to be formed in the mark portion 130 for identification. However, the type of mark is not limited to the data matrix and may be other symbols, characters, or shapes so long as the individual packages are identifiable. Laser irradiation, for example, can be used for forming the mark disposed on the mark portion 130. A laser used for forming the mark of the mark portion 130 includes a CO2 laser, a YVO4 laser, and the like, but other types of lasers may be used. That is, the mark for identification disposed on the mark portion 130 may be an engraving formed by engraving the surface 111 of the package 100 using laser irradiation or the like. Further, for example, the mark provided in the mark portion 130 may be formed using printing or the like.

In the example of the configuration illustrated in FIG. 1, a cavity structure 180 for storing the semiconductor chip in which a semiconductor element and the like are mainly formed is formed on the mounting surface 181 on which the semiconductor chip is to be mounted in the package 100. The surface 111 of the base plate 110 on which the mark portion 130 is disposed may thus be a surface opposite to the mounting surface 181 on which the semiconductor chip is mounted. By bonding a light transmitting member to a frame portion surrounding the cavity structure 180 of the mounting surface 181 of the base plate 110, for example, a structure that is hollow between the semiconductor chip disposed in the cavity structure 180 and the light transmitting member is formed. However, the configuration of the package 100 is not limited thereto, and the mounting surface 181 of the base plate 110 on which the semiconductor chip is mounted may, for example, be flat.

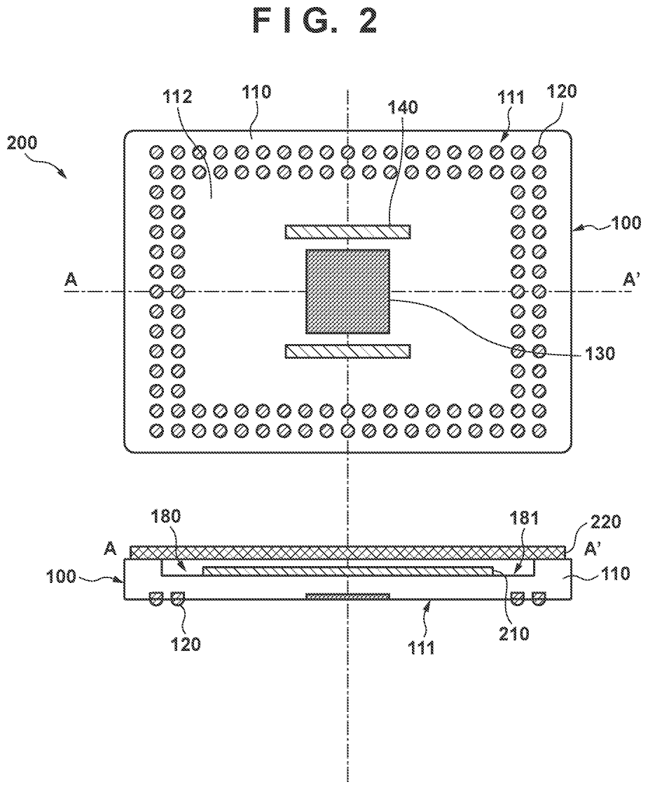

An example of a configuration of a semiconductor device 200 in which a semiconductor chip 210 is mounted on the package 100 will be described with reference to FIG. 2. FIG. 2 is a plan view and a cross-sectional view illustrating an example of a configuration of the semiconductor device 200 in which the semiconductor chip 210 is mounted on the package 100. The cross-sectional view illustrated on a lower side of FIG. 2 illustrates an A-A′ cross-section of the plan view illustrated in an upper side of FIG. 2.

The semiconductor device 200 may include the package 100, the semiconductor chip 210 mounted in the cavity structure 180 formed on the mounting surface 181 of the base plate 110 of the package 100, and a light transmitting member 220 disposed so as to cover the semiconductor chip 210. The semiconductor chip 210 includes, for example, a pixel region that has a plurality of light receiving elements, and a surface of the pixel region may be a light receiving surface. The pixel region may include, for example, color filters disposed on a light incident side of the light receiving elements, a planarizing film disposed on the color filters, and microlenses disposed on the planarizing film. The semiconductor chip 210 may be a CCD image sensor, a CMOS image sensor, or the like. The semiconductor chip 210 may include, for example, a pixel region that has a plurality of light emitting elements, and a surface of the pixel region may be a light emitting surface. The pixel region may include, for example, color filters disposed on light incident side of the light receiving elements, a planarizing film disposed on the color filters, and microlenses disposed on the planarizing film. The semiconductor chip 210 may be a liquid crystal display or an organic or inorganic electroluminescent (EL) display.

Electrodes for transmitting and receiving signals to and from the outside of the semiconductor chip 210 are provided in the semiconductor chip 210. The electrodes of semiconductor chip 210 are connected to the inner leads of the package 100 using conductors, such as gold wires. Wires made of copper, aluminum, or the like may be used for connection between the electrodes of the semiconductor chip 210 and the inner lead of the package 100.

Glass, quartz, plastic, or the like that transmits light may be used for the light transmitting member 220 disposed so as to cover the mounting surface 181 of the package 100 and the semiconductor chip 210. A material that has the same coefficient of linear expansion as a material used for the base plate 110 or the like of the package 100, for example, is selected as a material of the light transmitting member 220. Warping or deformation of the semiconductor device 200 may thus be suppressed.

Next, the smooth portion 140 disposed between the terminal 120 and the mark portion 130 on the surface 111 of the base plate 110 will be described in detail. The smooth portion 140 is provided on the surface 111 on which the terminals 120 to be subject to solder mounting for the base plate 110 are provided. The smooth portion 140 is disposed to suppress oozing of flux, which is contained in a solder material, from the terminal 120 onto the mark portion 130 at the time of solder mounting. As described above, when ceramic or the like is used as a material for the base plate 110, a surface of the base plate 110 is often porous, and a state of the surface is often rough. Therefore, there is an issue that the flux easily spreads over the surface 111 of the base plate 110 by capillary action. If flux oozes from the terminal 120 onto the mark during solder mounting, the mark for identification may become less visible. For example, it may make it difficult to identify individual packages 100 (semiconductor devices 200) in an inspection process or the like in which a camera is used. If the number of terminals 120 is increased, the package 100 is miniaturized, or the like, a distance between the terminal 120 and the mark portion 130 will be reduced, and the effect of the flux oozing may thus increase.

Therefore, the smooth portion 140, which is smoother than the portion 112 between the terminal 120 and the mark portion 130, excluding the smooth portion 140, is formed on the surface 111 of the base plate 110. It has been confirmed by the inventors that flux spreading at the time of solder mounting can be suppressed by the smooth portion 140. In the present embodiment, while an arithmetic mean roughness (Ra) of the portion 112 of the surface 111 of the base plate 110 is 4.0 μm, the Ra of the smooth portion 140 is 1.0 μm. That is, the Ra of the smooth portion 140 may be ¼ or less than the Ra of the portion 112. Further, for example, the Ra of the smooth portion 140 may be 1.0 μm or less. This makes it possible to suppress a decrease in the visibility of the mark portion 130 due to the flux oozing onto the mark portion 130.

In addition, according to experiments conducted by the inventors, it was found that if a width of the smooth portion 140 is 0.25 μm or more, the effect of suppressing the spreading of the flux will be achieved. Making the width of the smooth portion 140 as wide as possible makes it possible to suppress the spreading of the flux. Meanwhile, from the viewpoint of miniaturization of the package 100 (semiconductor device 200) and space saving, it is more suitable for the width of the smooth portion 140 to be not too large. For example, the width of the smooth portion 140 may be 1.0 μm or less. That is, the width of the smooth portion 140 may be 0.25 μm or more and 1.0 μm or less. For example, the width of the smooth portion 140 may be formed to be 0.75 μm.

As described above, the smooth portion 140 may be formed by irradiation with a CO2 laser or a YVO4 laser on the surface 111 of the base plate 110. For example, the smooth portion 140 may be formed using a similar method as the mark formed on the mark portion 130. That is, the mark for identification may be formed by irradiation with a CO2 laser or a YVO4 laser on the mark portion 130, and the smooth portion 140 may be formed similarly by irradiation with a CO2 laser or a YVO4 laser. For example, the smooth portion 140 may be formed in a step of forming the mark on the mark portion 130 or before or after the step of forming the mark. This makes it possible to form the smooth portion 140, which suppresses oozing of the flux at the time of solder mounting, while suppressing an increase in the number of steps. In this case, the surface of the smooth portion 140 may have a similar configuration to the surface of the mark provided on the mark portion 130. For example, the Ra of the surface of the smooth portion 140 may be substantially the same as the Ra of the surface of the mark of the mark portion 130. For example, a composition of the surface of the smooth portion 140 may be substantially the same as a composition of the surface of the mark of the mark portion 130. However, the method of forming the smooth portion 140 is not limited to irradiation with a laser and may be formed by printing a material that becomes smooth after firing, such as an alumina coat. A method of forming the smooth portion 140 may be any method so long as a surface smoother than the portion 112 between the terminal 120 and the mark portion 130, excluding the smooth portion 140, is obtained on the surface 111 of the base plate 110. In addition, a method of forming the mark provided in the mark portion 130 is not limited to irradiation with a laser, and the mark may be formed by printing a material, such as an alumina coat, or ink.

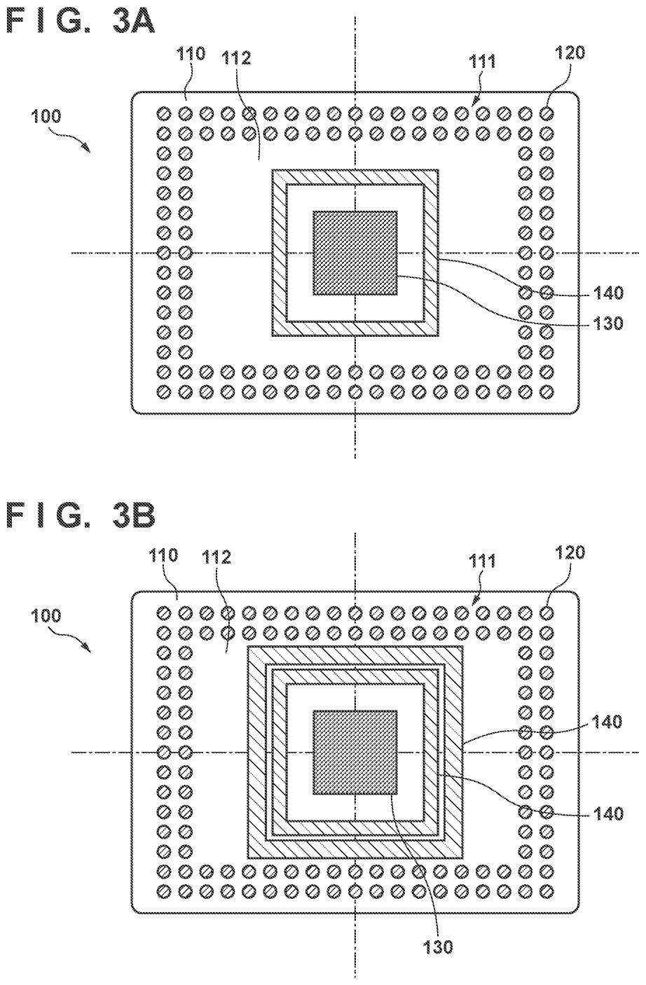

The smooth portion 140 exhibits a sufficient effect if provided at a location at which it can prevent the visibility of the mark portion 130 from being hindered due to the spreading of the flux. For example, as illustrated in FIG. 1, the smooth portion 140 may be disposed in a portion where the distance between the terminal 120 and the mark portion 130 is short. In addition, for example, as illustrated in FIG. 3A, if the layout allows for the arrangement, the smooth portion 140 may be disposed in a ring shape so as to surround the mark portion 130. Further, as illustrated in FIG. 3B, the smooth portion 140 may be disposed so as to surround the mark portion 130 in a plurality of lines. By providing a plurality of lines of the smooth portion 140, it is possible to more reliably suppress oozing of the flux into the mark portion 130 even when, for example, a solder material that contains a large amount of flux component, such as resin reinforced solder, is used. As a result, it becomes possible to shorten the distance between the terminal 120 and the mark portion 130 and thus miniaturize the package 100. Here, both in FIGS. 3A and 3B, the unbroken, ring-shaped smooth portion 140 surrounds the mark portion 130; however, the smooth portion 140 may be in a form in which a portion of the ring of the smooth portion 140 is broken (discontinuous). For example, the smooth portion 140 may be formed at locations facing the respective sides of the rectangular mark portion 130, and the smooth portion 140 need not be formed in portions corresponding to corner portions of the mark portion 130.

The package 100 in which the above-described smooth portion 140 is disposed and the semiconductor device 200 in which the semiconductor chip 210 is mounted on the package 100 are used. Thus, oozing of the flux from the terminal 120 onto the mark portion 130, in which the mark is provided, due to solder mounting is suppressed. As a result, it is possible to ensure the visibility of the mark for identification formed in the mark portion 130 and miniaturize the package 100 (semiconductor device 200).

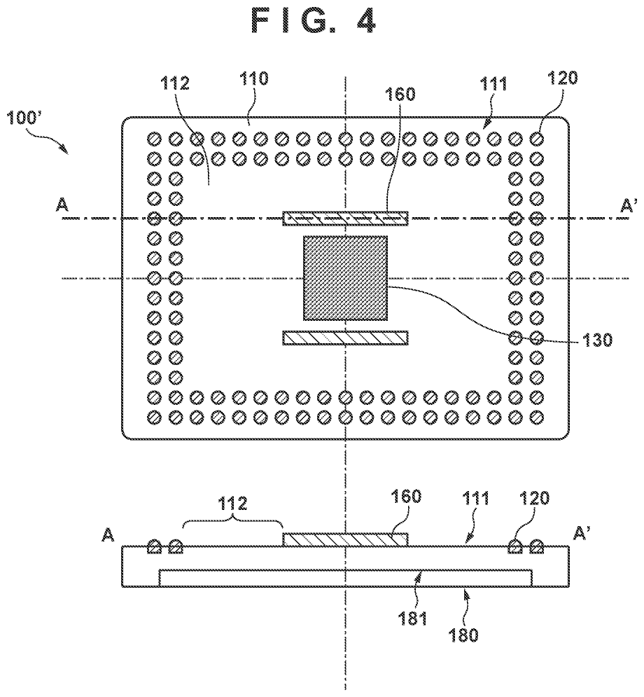

FIG. 4 is a plan view and a cross-sectional view of the package 100′ illustrating a variation of the above-described package 100. The cross-sectional view illustrated on a lower side of FIG. 4 illustrates an A-A′ cross-section of the plan view illustrated in an upper side of FIG. 4. When compared to the configuration of the package 100 illustrated in FIG. 1, in the package 100′ illustrated in FIG. 4, a convex portion 160, which protrudes from the surface 111 of the base plate 110 in a direction of the normal of the surface 111, is disposed instead of the smooth portion 140. More specifically, the convex portion 160, which protrudes more than another portion 112 between the plurality of terminals 120 and the mark portion 130, is provided between at least one terminal among the plurality of terminals 120 and the mark portion 130 on the surface 111 of the base plate 110. The configuration of the package 100′ besides this may be similar to the configuration of the above-described package 100, and so, description will be given mainly on the convex portion 160.

Similarly to the smooth portion 140, the convex portion 160 is provided on the surface 111 on which the terminals 120, which are associated with solder mounting for the base plate 110, are provided. The convex portion 160 is disposed for suppressing oozing of flux, which is contained in a solder material, from the terminal 120 onto the mark portion 130 at the time of solder mounting. Specifically, by the convex portion 160 being provided, the spreading of the flux component from the terminal 120 onto the mark portion 130 is suppressed. As a result, it becomes possible to shorten the distance between the terminal 120 and the mark portion 130 and thus miniaturize the package 100′.

In the package 100′ illustrated in FIG. 4, similarly to the configuration illustrated in FIG. 2, the semiconductor chip 210 may be mounted on the mounting surface 181 and the package 100′ may constitute a portion of the semiconductor device 200. As illustrated in FIG. 4, similarly to the package 100, the cavity structure 180 for storing the semiconductor chip 210 or the like may be formed on the mounting surface 181 on which the semiconductor chip 210 of the package 100′ is to be mounted.

In a case such as when the base plate 110 of the package 100′ is formed of ceramic, the convex portion 160 may be formed by recessing a portion of a mold for forming the base plate 110 that corresponds to the convex portion 160. Further, for example, the convex portion 160 may be formed by further arranging a suitable material, such as an alumina coat or resin, on the surface 111 of the flat base plate 110. For example, a surface of the convex portion 160 may be smoother than a surface of the portion 112 between the terminal 120 and the mark portion 130, excluding the convex portion 160.

The convex portion 160 exhibits a sufficient effect if provided at a location at which it can prevent the visibility of the mark portion 130 from being hindered due to the spreading of the flux. For example, as illustrated in FIG. 4, the convex portion 160 may be disposed in a portion where the distance between the terminal 120 and the mark portion 130 is short. In addition, for example, similarly to the package 100 illustrated in FIG. 3A, if the layout allows for the arrangement, the convex portion 160 may be disposed in a ring shape so as to surround the mark portion 130. Further, as illustrated in FIG. 3B, the convex portion 160 may be disposed so as to surround the mark portion 130 in a plurality of lines.

Regarding a height of the convex portion 160, making the height of the convex portion 160 as high as possible can be considered in view of the characteristic as a wall structure for suppressing spreading of the flux. According to experiments conducted by the inventors, it was found that if the convex portion 160 is 1 μm or more protruded than another portion 112 between the terminal 120 and the mark portion 130, the effect of sufficiently suppressing spreading of the flux will be achieved. For example, the height of the convex portion 160 may be 5 μm. However, if the convex portion 160 is made too high, an issue may occur in the connection between the terminals 120 and terminals external to the package 100 (semiconductor device 200) that are to be connected to the terminal 120 at the time of solder mounting. Therefore, an appropriate height may be selected depending on a height of the terminals 120 and a size of a solder ball to be used, for example. The height of the convex portion 160 may be, for example, 1 μmm or less, 500 μm or less, 100 μm or less or 10 μm or less.

The package 100′ in which the above-described convex portion 160 is disposed and the semiconductor device 200 in which the semiconductor chip 210 is mounted on the package 100′ are used. Thus, oozing of the flux from the terminal 120 onto the mark portion 130, in which the mark is provided, due to solder mounting is suppressed. As a result, it is possible to ensure the visibility of the mark for identification formed in the mark portion 130 and miniaturize the package 100′ (semiconductor device 200).

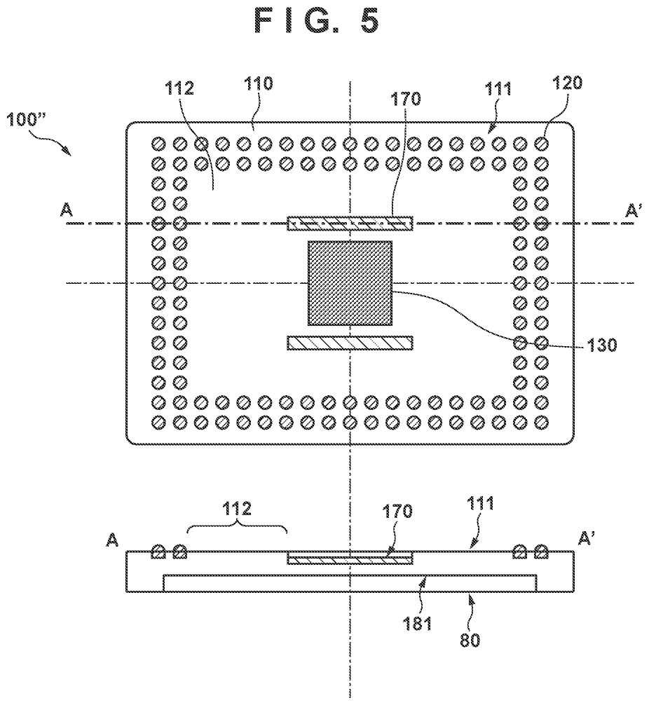

FIG. 5 is a plan view and a cross-sectional view of a package 100″ illustrating a variation of the above-described packages 100 and 100′. The cross-sectional view illustrated on a lower side of FIG. 5 illustrates an A-A′ cross-section of the plan view illustrated in an upper side of FIG. 5. When compared to the configuration of the package 100 illustrated in FIG. 1, in the package 100″ illustrated in FIG. 5, a concave portion 170, which is recessed from the surface 111 of the base plate 110 in a direction of the normal of the surface 111, is disposed instead of the smooth portion 140. More specifically, the concave portion 170, which is more recessed than another portion 112 between the plurality of terminals 120 and the mark portion 130, is provided between at least one terminal among the plurality of terminals 120 and the mark portion 130 on the surface 111 of the base plate 110. The configuration of the package 100″ besides this may be similar to the configuration of the above-described package 100, and so, description will be given mainly on the concave portion 170.

Similarly to the smooth portion 140, the concave portion 170 is provided on the surface 111 on which the terminals 120, which are associated with solder mounting for the base plate 110, are provided. The concave portion 170 is disposed for suppressing oozing of flux, which is contained in a solder material, from the terminal 120 onto the mark portion 130 at the time of solder mounting. Specifically, by the concave portion 170 being provided, spreading of the flux component from the terminal 120 onto the mark portion 130 is suppressed. As a result, it becomes possible to shorten the distance between the terminal 120 and the mark portion 130 and thus miniaturize the package 100″.

In the package 100″ illustrated in FIG. 5, similarly to the configuration illustrated in FIG. 2, the semiconductor chip 210 may be mounted on the mounting surface 181 and the package 100″ may constitute a portion of the semiconductor device 200. As illustrated in FIG. 5, similarly to the package 100, the cavity structure 180 for storing the semiconductor chip 210 or the like may be formed on the mounting surface 181 on which the semiconductor chip 210 of the package 100″ is to be mounted.

In a case such as when the base plate 110 of the package 100″ is formed of ceramic, the concave portion 170 may be formed by causing a portion of a mold for forming the base plate 110 that corresponds to the concave portion 170 to be protruded. Further, for example, the concave portion 170 may be formed by cutting the surface 111 of the base plate 110.

The concave portion 170 exhibits a sufficient effect if provided at a location at which it can prevent the visibility of the mark portion 130 from being hindered due to the spreading of the flux. For example, as illustrated in FIG. 5, the concave portion 170 may be disposed in a portion where the distance between the terminal 120 and the mark portion 130 is short. In addition, for example, similarly to the package 100 illustrated in FIG. 3A, if the layout allows for the arrangement, the concave portion 170 may be disposed in a ring shape so as to surround the mark portion 130. Further, as illustrated in FIG. 3B, the concave portion 170 may be disposed so as to surround the mark portion 130 in a plurality of lines.

Regarding a depth of the concave portion 170, it is more suitable for it to be as deep as possible in view of the characteristic of suppressing advancement of the flux by storing the flux in the concave portion 170 (groove). However, for example, if a groove that serves as the concave portion 170 is formed by cutting on the surface 111 of the base plate 110, when the depth of the concave portion 170 is increased, a processing time of a step of forming the concave portion 170 increases. Further, for example, when the depth of the concave portion 170 is increased, a strength of the base plate 110 may decrease. As a result of extensive studies conducted by the inventors, it was found that if the concave portion 170 is more recessed than another portion 112 between the terminal 120 and the mark portion 130 by 2 μm or more, a sufficient effect will be achieved. For example, the depth of the concave portion 170 may be 5 μm. Further, the depth of the concave portion 170 may be, for example, 1 μmm or less, 500 μm or less, 100 am or less, or 10 μm or less in view of the step of forming the concave portion 170 and the strength of the base plate 110.

The package 100″ in which the above-described concave portion 170 is disposed and the semiconductor device 200 in which the semiconductor chip 210 is mounted on the package 100″ are used. Thus, oozing of the flux from the terminal 120 onto the mark portion 130, in which the mark is provided, due to solder mounting is suppressed. As a result, it is possible to ensure the visibility of the mark for identification formed in the mark portion 130 and miniaturize the package 100″ (semiconductor device 200).

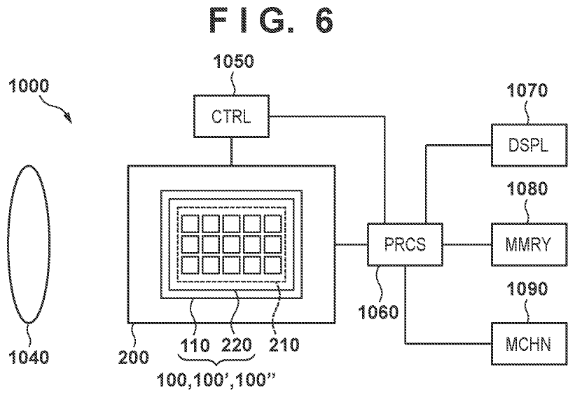

The following describes an apparatus 1000, which includes the above-described package 100, 100′, or 100″ and the semiconductor device 200, which includes the semiconductor chip 210 mounted on the package 100, 100′, or 100″, illustrated in FIG. 6. The semiconductor chip 210 is stored in the package 100, 100′, or 100″ and mounted on the apparatus 1000. In the configuration illustrated in FIG. 6, the semiconductor chip 210 is a photoelectric conversion device. The semiconductor device 200 may include the package 100, 100′, or 100″, which includes the base plate 110 to which the semiconductor chip 210 is fixed and the light transmitting member 220, which faces the semiconductor chip 210 and is made of glass or the like. In the packages 100, 100′, and 100″, bonding members, such as wires and bumps for connecting the inner leads provided on the base plate 110 and terminals, such as pad electrodes, provided on the semiconductor chip 210, may be disposed as described above.

The apparatus 1000 can include at least one of an optical device 1040, a control device 1050, a processing device 1060, a display device 1070, a storage device 1080, and a mechanical device 1090. The optical device 1040 is, for example, a lens, a shutter, and a mirror. The control device 1050 controls the semiconductor chip 210. The control device 1050 is, for example, a semiconductor device, such as an ASIC.

The processing device 1060 processes a signal output from the semiconductor chip 210. The processing device 1060 is a semiconductor device, such as a CPU or an ASIC, for configuring an analog front end (AFE) or a digital front end (DFE). The display device 1070 is an EL display device and a liquid crystal display device for displaying information (an image) obtained by the semiconductor chip 210. The storage device 1080 is a magnetic device or a semiconductor device for storing information (an image) obtained by the semiconductor chip 210. The storage device 1080 may be a volatile memory, such as an SRAM or a DRAM, or a non-volatile memory, such as a flash memory or a hard disk drive.

The mechanical device 1090 includes a moving unit or a propulsion unit, such as a motor or engine. In the apparatus 1000, a signal output from the semiconductor chip 210 is displayed on the display device 1070 or transmitted to the outside by a communication device (not illustrated) included in the apparatus 1000. To this end, the apparatus 1000 may further include the storage device 1080 and the processing device 1060 in addition to a storage circuit and an arithmetic circuit included in the semiconductor chip 210. The mechanical device 1090 may be controlled based on a signal output from the semiconductor chip 210.

The apparatus 1000 is suitable for an electronic device, such as an information terminal (e.g., a smartphone or a wearable terminal) that has an image capturing function or a camera (e.g., an interchangeable lens camera, a compact camera, a video camera, or a surveillance camera). The mechanical device 1090 in the camera can drive components of the optical device 1040 for zooming and focusing as well as shutter operation. Alternatively, the mechanical device 1090 in the camera can move the semiconductor chip 210 for image stabilization operation.

The apparatus 1000 may also be a transportation apparatus, such as a vehicle, a ship, or an airplane. The mechanical device 1090 in the transportation apparatus may be used as a moving device. The apparatus 1000 that serves as a transportation apparatus is suitable for transporting the semiconductor chip 210 or for assisting and/or automating driving (maneuvering) using an image capturing function. The processing device 1060 for assisting and/or automating driving (maneuvering) can perform processing for operating the mechanical device 1090 that serves as the moving device based on information obtained by semiconductor chip 210. Alternatively, the apparatus 1000 may be a medical apparatus such as an endoscope, a measurement apparatus such as a ranging sensor, an analytical apparatus such as an electron microscope, an office apparatus such as a multifunction peripheral, or an industrial apparatus such as a robot.

According to the present disclosure, it is possible to provide a technique for suppressing a decrease in visibility of a mark for identification.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-193608, filed Dec. 2, 2022, which is hereby incorporated by reference herein in its entirety.

What is claimed is:

1. A package comprising:
a plurality of terminals;
a mark portion on which a mark for identification is provided; and
a base plate,
wherein the plurality of terminals and the mark portion are provided on one surface of the base plate, and
wherein a smooth portion, which is smoother than another portion between the plurality of terminals and the mark portion, is provided on the one surface and between at least one terminal among the plurality of terminals and the mark portion.

2. The package according to claim 1, wherein the smooth portion is disposed so as to surround the mark portion.

3. The package according to claim 1, wherein the mark for identification is a data matrix.

4. The package according to claim 1, wherein an arithmetic mean roughness of the smooth portion is ¼ or less of an arithmetic mean roughness of the other portion.

5. The package according to claim 1, wherein an arithmetic mean roughness of the smooth portion is 1.0 micrometer (μm) or less.

6. The package according to claim 1, wherein a width of the smooth portion is 0.25 micrometer (μm) or more and 1.0 μm or less.

7. The package according to claim 1, wherein a surface of the smooth portion has a similar configuration to that of a surface of the mark for identification provided in the mark portion.

8. The package according to claim 1, wherein the base plate is an insulating base plate.

9. The package according to claim 1, wherein the base plate includes alumina or steatite.

10. The package according to claim 1, wherein the mark portion is disposed in a central region of the one surface.

11. The package according to claim 1, wherein the one surface is a surface opposite to a mounting surface on which a semiconductor chip is to be mounted.

12. A package comprising:
a plurality of terminals;
a mark portion on which a mark for identification is provided; and
a base plate,
wherein the plurality of terminals and the mark portion are provided on one surface of the base plate, and
wherein a convex portion, which is more protruded than another portion between the plurality of terminals and the mark portion, is provided on the one surface and between at least one terminal among the plurality of terminals and the mark portion.

13. The package according to claim 12, wherein the convex portion is disposed so as to surround the mark portion.

14. The package according to claim 12, wherein the mark for identification is a data matrix.

15. The package according to claim 12, wherein the convex portion is more protruded than the other portion by 1 micrometer (μm) or more.

16. A package comprising:
a plurality of terminals;
a mark portion on which a mark for identification is provided; and
a base plate,
wherein the plurality of terminals and the mark portion are provided on one surface of the base plate, and
wherein a concave portion, which is more recessed than another portion between the plurality of terminals and the mark portion, is provided on the one surface and between at least one terminal among the plurality of terminals and the mark portion.

17. The package according to claim 16, wherein the concave portion is disposed so as to surround the mark portion.

18. The package according to claim 16, wherein the mark for identification is a data matrix.

19. The package according to claim 16, wherein the concave portion is more recessed than the other portion by 2 micrometer (μm) or more.

20. A semiconductor device comprising:
the package according to claim 1; and
a semiconductor chip mounted on the package.

21. An apparatus comprising:
a semiconductor device having the package according to claim 1, and a semiconductor chip mounted on the package; and
a processing device configured to process a signal output from the semiconductor device.
